(19) United States
(12) Patent Application Publication
(10) Pub. No.: US 2025/0355045 A1
(43) Pub. Date: Nov. 20, 2025

(54) ACOUSTIC DEVICE FOR ESTIMATING A TRIGGER INTENSITY, ELECTRICAL PROTECTION ASSEMBLY AND ASSOCIATED ELECTRICAL INSTALLATION

(71) Applicant: Schneider Electric Industries SAS, Rueil-Malmaison (FR)

(72) Inventors: David Lanes, Saint Hilaire du Touvet (FR); Christophe Grumel, Lans en Vercors (FR); Nicolas Laydevant, Grenoble (FR)

(73) Assignee: Schneider Electric Industries SAS, Rueil-Malmaison (FR)

(21) Appl. No.: 19/204,727

(22) Filed: May 12, 2025

(30) Foreign Application Priority Data
May 17, 2024 (FR) 2405098

(51) Int. Cl. G01R 31/327; H01H 9/54; H04R 1/08; H04R 1/28; H04R 3/00

(52) U.S. Cl. CPC G01R 31/3277; H01H 9/54; H04R 1/086; H04R 1/2892; H04R 3/00

(57) ABSTRACT

This invention relates to an acoustic device for estimating a trigger intensity of a trip current flowing in a circuit breaker, the device comprising:
a casing (22);
a plate (32);
a support (40), a tab (42) connecting the support and the plate;
a microphone (70);
an attenuator (44), the support extending between the microphone and the attenuator, the attenuator comprising a housing (46) with a housing orifice (48) and an attenuating membrane (50); and
an electronic control unit (38), connected to the microphone,
   the attenuator being configured to attenuate noise generated by the circuit breaker, the noise being representative of the trigger intensity, the microphone being configured to measure the noise attenuated by the attenuator, and emit an output signal, and the electronic control unit being configured to receive the output signal and estimate the trigger intensity.

### FIELD

This invention relates to an acoustic device for estimating a trigger intensity, an electrical protection assembly, and an associated electrical installation.

### BACKGROUND

To monitor the operation of a circuit breaker and predict maintenance operations, it is known to measure the current intensity flowing through the circuit breaker when it trips, i.e., becomes electrically isolating. The current flowing through the circuit breaker when it trips is called the trip current, and its intensity is known as the trip intensity.

However, measuring the trip intensity is costly and intrusive, as it requires adding a current sensor inside the circuit breaker, specifically on one of the conductors, which must withstand high trip intensities.

### SUMMARY

The invention aims to propose a device that estimates the trip intensity simply, non-intrusively, and at low cost.

To this end, the invention concerns an acoustic device for estimating a trip intensity of a trip current flowing in a circuit breaker, the device comprising:
a casing configured to be attached to the circuit breaker;
a plate integrated inside the casing, extending along a main plane;
a support integrated inside the casing, extending parallel to the main plane, a tab connecting the support and the plate, the support being connected to the plate only via the tab;
a microphone fixed to the support;
an attenuator fixed to the support, the support extending between the microphone and the attenuator, the attenuator comprising:
   a housing with a housing orifice, passing through and extending along a housing axis, and
   an attenuating membrane received in the housing and covering the housing orifice;
an electronic control unit connected to the microphone,
the attenuator being configured to attenuate noise generated by the circuit breaker, the noise being representative of the trip intensity, the microphone being configured to measure the noise attenuated by the attenuator and to emit an output signal representative of the attenuated noise, and the electronic control unit being configured to receive the output signal emitted by the microphone and to estimate the trip intensity of the circuit breaker's trip current from the output signal.

By means of the invention, estimating the trip intensity using the noise emitted by the circuit breaker is simple, non-intrusive, and low-cost. Indeed, since the noise emitted by the circuit breaker is representative of the trip intensity, estimating the trip intensity from the noise measured by the microphone is a simple and inexpensive solution. Moreover, the microphone does not need to be integrated into the circuit breaker to function. The attenuator, particularly by means of the attenuating membrane, allows the noise emitted by the circuit breaker to be attenuated to sound levels that can be measured by the microphone, while offering constant attenuation over the frequency range composing the noise. This limits the risk of saturation and damage to the microphone while allowing the microphone to record attenuated noise representative of the trip intensity, so that the electronic unit estimates the trip intensity with the best possible accuracy.

The fact that the support is connected to the plate only via the tab allows mechanical vibrations generated by the circuit breaker and transmitted to the device to be damped, to limit the masking of the attenuated noise by the measurement thereof by the microphone and preventing a correct estimation of the trip intensity.

According to other advantageous aspects of the invention, the acoustic device comprises one or more of the following features, taken individually or in all technically possible combinations:
the attenuator further comprises a washer with a washer orifice, the washer orifice passing through and extending along a washer axis, the washer being received in the housing so that the housing and washer axes coincide, the washer being in contact with the attenuating membrane, and the attenuating membrane covering the washer orifice.
the device further comprises a mechanical damper fixed to the casing, surrounding the support and the attenuator, and leaving the microphone and the housing orifice free, the mechanical damper being configured to damp mechanical vibrations of the device.
The casing comprises a shim, the tab being supported against the shim to position the support at a distance from the plate along an axis perpendicular to the main plane.
The support comprises a support orifice, the support orifice being passing through along a support axis;
the microphone is fixed on the support to cover the support orifice; and
the attenuator is fixed to the support so that the housing, washer, and support axes coincide.
The casing comprises an acoustic port with at least one opening, the support facing the acoustic port, and the attenuator positioned between the support and the acoustic port.
The attenuator is fixed to the support by an adhesive film, the adhesive film comprising at least two adhesive layers and at least one membrane, interposed between two of the at least two adhesive layers, one of the at least two adhesive layers being glued to the attenuator and another of the at least two adhesive layers being glued to the support.
The or each membrane comprises woven fibers.
The or each membrane comprises non-woven fibers.

The invention also concerns an electrical protection assembly comprising a circuit breaker, the circuit breaker being configured to be connected between a source and a load, and being configured to switch from an armed configuration, wherein the circuit breaker conducts a current flowing between the source and the load, to a tripped configuration, wherein the circuit breaker electrically isolates the load from the source, when a trip current of trip intensity flows in the circuit breaker, the switch from the armed configuration to the tripped configuration generating noise representative of the trip intensity, the circuit breaker comprising a housing, the electrical protection assembly further comprising a device as described above, the device's casing being fixed to the housing.

The invention also concerns an electrical installation comprising a source, a load connected to the source, and an electrical protection assembly connected between the source and the load.

### BRIEF DESCRIPTION OF THE DRAWINGS

The invention will become clearer upon reading the following description, given solely as a non-limiting example, and made with reference to the drawings wherein:

FIG. 1 is a view of an electrical installation according to the invention;

FIG. 2 is a section of a protection device according to the invention;

FIG. 3 is an exploded view of elements of the protection device;

FIG. 4 is a view of a detail of the protection device according to the plane IV-IV.

### DETAILED DESCRIPTION

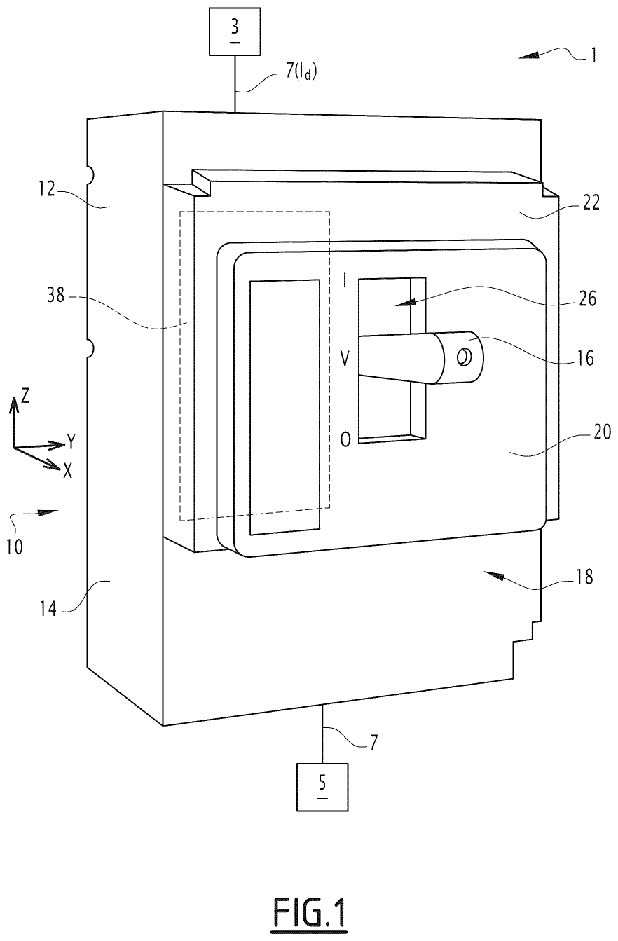

FIG. 1 represents an electrical installation 1, comprising a source 3 and a load 5. The source 3 provides electricity and is, for example, an electrical generator, a transformer, or an electrical network like a mains electrical network. The load 5 is a device consuming electricity, for example, an industrial equipment item such as an electric motor, a server, or a domestic appliance.

In the example of FIG. 1, the source 3 and the load 5 are connected by a phase conductor 7, but alternatively, the source and the load are connected by more than one phase conductor, for example, three phase conductors. An electrical current, also simply called current, provided by the source 3, flows between the source 3 and the load 5 through the phase conductor 7. The electrical current is advantageously a low-voltage electrical current, i.e., with a nominal voltage less than or equal to 1500V. The current is advantageously an alternating current. Alternatively, the current is a direct current.

Advantageously, and not shown, the source 3 and the load 5 are also connected by a neutral conductor.

The electrical installation 1 comprises an electrical protection assembly 10, connected between the source 3 and the load 5. The electrical protection assembly 10 comprises a circuit breaker 12, which is connected between the source 3 and the load 5. Thus, the current flowing from the source 3 to the load 5 through the phase conductor 7 also flows through the circuit breaker 12. The circuit breaker 12 is, for example, as shown in FIG. 1, a molded case circuit breaker, or MCCB.

The circuit breaker 12 comprises a housing 14, which is made of an electrically insulating material. The housing 14 contains most of the other components of the circuit breaker 12, including the circuit breaker contacts, not shown.

The circuit breaker 12 is configured to switch between an armed configuration, wherein the contacts are closed, and wherein said circuit breaker conducts the current flowing between the source 3 and the load 5, and a tripped configuration, wherein the contacts are open and wherein said circuit breaker electrically isolates the source 3 from the load 5. The circuit breaker 12 is configured to switch to the tripped configuration in case of a short circuit or overload of the electrical installation 1, to prevent too much current from flowing in the electrical installation 1. The circuit breaker 12 is also configured to switch to the tripped configuration following a user command, for example, manually switching the circuit breaker 12 to the tripped configuration by operating a lever 16 of the circuit breaker 12. When the circuit breaker 12 switches to the tripped configuration, the current flowing in the circuit breaker 12 is called the trip current, and is characterized by a trip intensity Id. The trip intensity Id varies depending on the reason for the circuit breaker 12 switching to the tripped configuration, and can range from nearly zero, for example, when the user commands the circuit breaker 12 to switch to the tripped configuration, to greater than 2500 A, for example, in the case of short circuits.

In the example of FIG. 1, the lever 16 protrudes from a front face 18 of the housing 14. The front face 18 is perpendicular to a depth axis X, related to the circuit breaker 12. A width axis Y and a height axis Z are associated with the depth axis X, the three axes forming a right-handed triad. The front face 18 thus extends along the width Y and height Z axes.

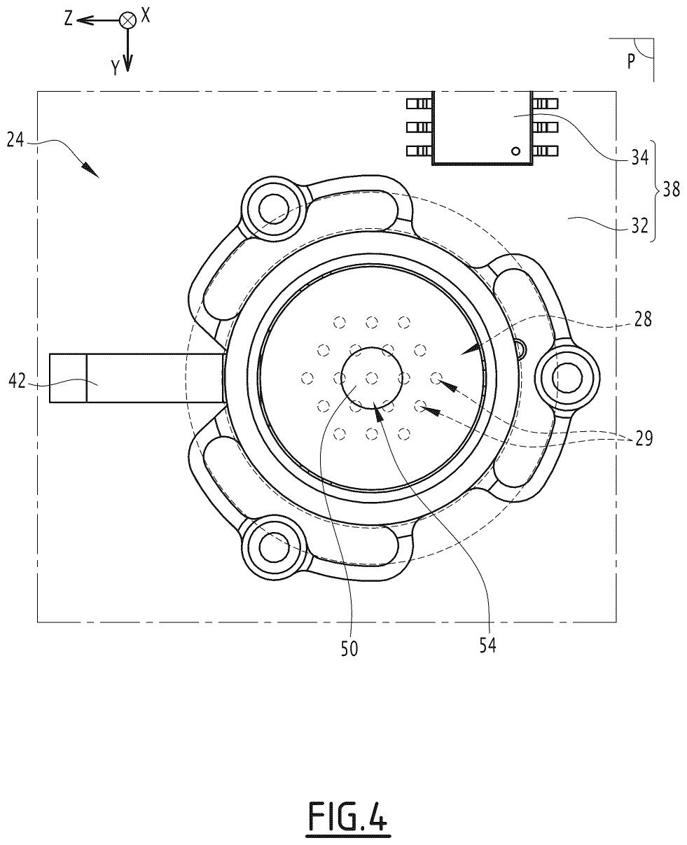

The electrical assembly 10 also comprises an acoustic device 20 for estimating the trip intensity Id. The device 20 comprises a casing 22, fixed to the circuit breaker 12. More precisely, the casing 22 is fixed to the housing 14, for example, by being glued or screwed to the housing 14. In the example of FIG. 1, the casing 22 comprises a rear face 24, partially visible in FIG. 4, which is in contact with the front face 18. Alternatively, the rear face 24 of the casing 22 is at a distance of a few millimeters from the front face 18 of the housing 14, measured along the depth axis X. The casing 22 comprises an orifice 26, which passes through same to allow the lever 16 to move freely when the circuit breaker 12 trips, when the circuit breaker 12 is reset by the user, or when the user operates the lever 16 to manually trip the circuit breaker 12.

Advantageously, the casing 22 comprises an acoustic port 28, visible in FIG. 4. In the example of FIGS. 1 and 4, the acoustic port 28 is located on the rear face 24, to be in contact with the front face 22, or at least, as close as possible to the circuit breaker 12. The acoustic port 28 comprises at least one opening 29, in the example of FIG. 4, a plurality of openings 29, connect the inside of the casing 22 to the outside. Air can thus circulate from the outside to the inside of the casing 22 through the openings 29 and vice versa.

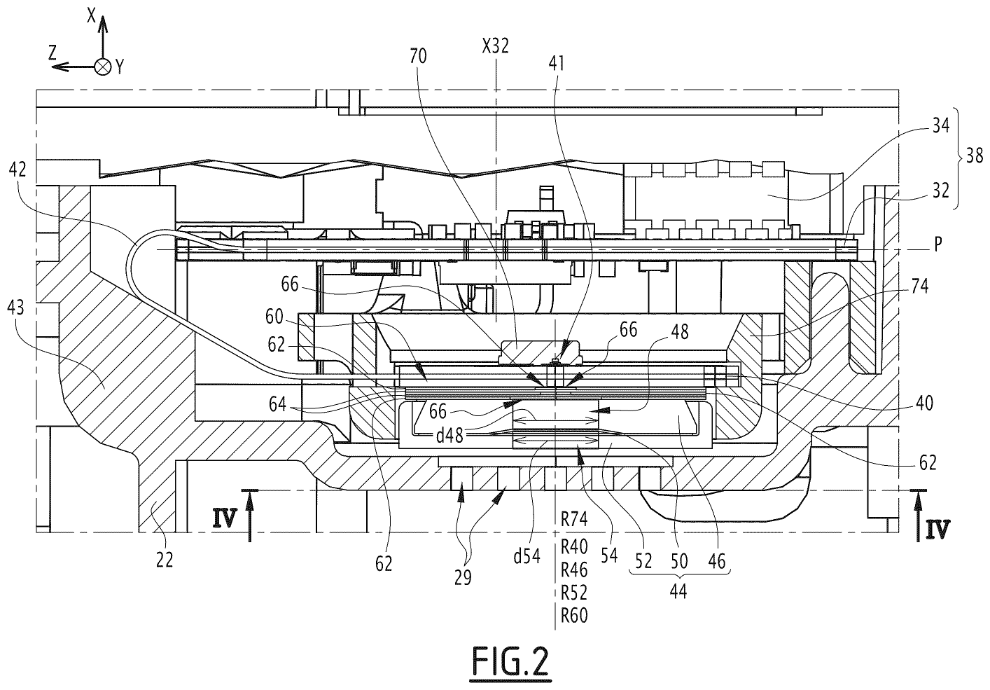

The device 20 also comprises a plate 32, visible in FIGS. 2 and 4, integrated inside the casing 22. The plate 32 extends along a main plane P, which, in the example of FIGS. 2 and 4, is perpendicular to the depth axis X.

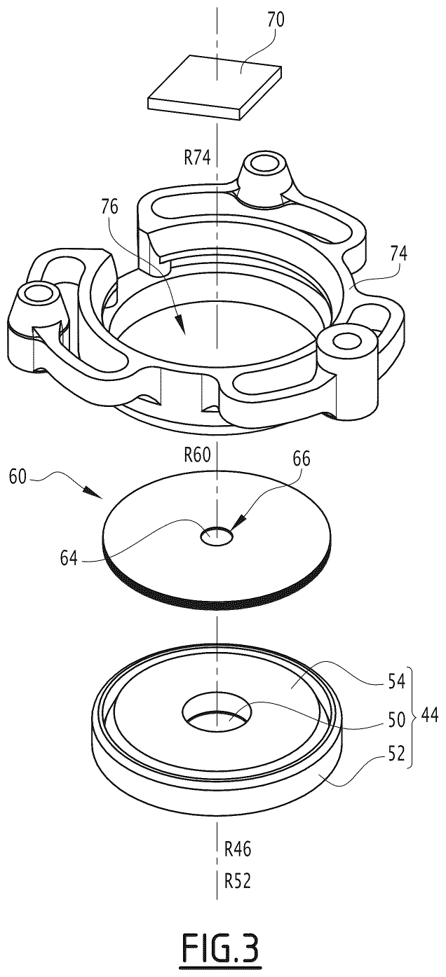

The plate 32 is, for example, a printed circuit board, on which electronic components 34 are connected, such as programmable logic components, like FPGAs (Field Programmable Gate Array), or integrated circuits, such as ASICs (Application Specific Integrated Circuit), the printed circuit board and the electronic components 34 forming an electronic control unit 38, represented in dashed lines in FIG. 1, and partially in FIGS. 2 and 3, the function thereof being described in detail hereinbelow.

The device 20 comprises a support 40, integrated inside the casing 22 and visible in FIG. 2. In the example of FIG. 2, the support 40 is circular and extends parallel to the main plane P. The support 40 is, for example, a printed circuit board. Advantageously, the support 40 comprises a support orifice 41, passing through and extending along a support axis R40.

Advantageously, the support 40 is at a distance from the plate 32 along an axis X32, perpendicular to the main plane P.

The support 40 is connected to the plate 32 via a tab 42. The support 40 is connected to the plate 32 only via this tab 42. The tab 42 is advantageously made of flexible polymer, for example, polyimide, or alternatively, the tab 42 is itself a flexible printed circuit board.

Advantageously, to position the support 40 at a distance from the plate 32 along the axis X32, the casing 22 comprises a shim 43, visible in FIG. 2. The tab 42 is supported against the shim 43 and constrained by the shim 43 to position the support 40 while limiting the constraints applied to it.

The device 20 also comprises an attenuator 44, fixed to the support 40. The attenuator 44 comprises a housing 46, with a housing orifice 48. The housing orifice 48 is passing through and extends along a housing axis R46. The housing 46 is advantageously circular and made of metal, for example, aluminum. Advantageously, the housing orifice 48 is aligned with the support orifice 41, so that the support and housing axes R40 and R46 coincide.

The attenuator 44 also comprises an attenuating membrane 50, received in the housing 46 and covering the housing orifice 48. The attenuating membrane 50 is advantageously made of an air-tight material, for example, polyimide. Advantageously, the thickness of the attenuating membrane 50, measured along the axis X32, is less than 100 μm, for example, equal to 75 μm.

Advantageously, the attenuator 44 also comprises a washer 52. The washer 52 comprises a washer orifice 54, passing through and extending along a washer axis R52. Advantageously, the washer orifice 54 has a diameter d54 less than 4 mm, for example, equal to 3.5 mm and equal to a diameter d48 of the housing orifice 48. The washer 52 is advantageously made of metal, for example, aluminum. The washer 54 is received in the housing 46, for example, by being crimped in the housing 46, so that the housing 46 and the washer 52 are each in contact with the attenuating membrane 50. The attenuating membrane 50 thus covers both the housing orifice 48 and the washer orifice 54. The membrane 50 is thus exposed to air through the housing orifice 40 and the washer orifice 54, while being air-tight, as described previously.

Advantageously, the washer 54 is received in the housing 46 so that the housing and washer axes R46 and R52 coincide. Thus, the support, housing, and washer axes R40, R46, and R52 coincide.

Advantageously, the attenuator 44 is fixed to the support 40 by an adhesive film 60. The adhesive film 60 comprises at least two adhesive layers 62 and at least one membrane 64, interposed between two of the at least two adhesive layers 62. The adhesive film 60 is visible in FIGS. 2 and 3, and in the example of FIGS. 2 and 3, comprises three double-sided adhesive layers 62 and two membranes 64, each membrane 64 being interposed between two adhesive layers 62. The adhesive layers 62 and the membranes 64 are thus glued to each other. To fix the attenuator 44 to the support 40, one of the adhesive layers 62 is glued to the attenuator 44 and another of the adhesive layers 62 is glued to the support 40.

Advantageously, the adhesive layers 62 each comprise an orifice 66, passing through, each orifice 66 being along a film axis R60. Advantageously, the diameter of the orifices 66 is variable, as visible in FIG. 2. Alternatively, the orifices 66 of the adhesive layers 62 all have the same diameter. The membranes 64 do not comprise an orifice and thus cover the orifices 66.

Advantageously, the membranes 64 comprise woven fibers, or alternatively, non-woven fibers.

Advantageously, the membranes 64 are air-tight, and the adhesive film 60 seals the attenuator 44 and the support orifice 41 to air.

The device 20 also comprises a microphone 70, fixed on the support 40, the support 40 extending between the microphone 70 and the attenuator 44. Advantageously, the microphone 70 covers the support orifice 41. The microphone 70 is advantageously a micro-electromechanical systems microphone, or MEMS. The microphone 70 is connected to the electronic control unit 38, for example, by being connected to one of the electronic components 34. The microphone 70 is configured to measure ambient noise, i.e., the mechanical vibrations of the air surrounding it. In the case where the microphone 70 is a MEMS microphone, it is configured to measure noise up to about 135 dB, beyond which it saturates.

Advantageously, the device 20 also comprises a mechanical damper 74. The mechanical damper 74 is fixed to the casing 22, and advantageously, is supported against the plate 32. The mechanical damper 74 surrounds the support 40 and the attenuator 44. In particular, the mechanical damper 74 comprises a central opening 76, passing through, and extending along a damper axis R74, wherein the support 40 is inserted, blocking the central opening 76.

Advantageously, the mechanical damper 74 is made of an elastomeric material, such as silicone. The mechanical damper 74 is advantageously tightly mounted around the support 40, the support 40 being inserted into the central opening 76, for example, by elastic or plastic deformation of the mechanical damper 74.

The mechanical damper 74 leaves the microphone 70 and the housing orifice 48 free, i.e., the mechanical damper 74 is not in contact thereof, for example, does not cover the housing orifice 48.

Advantageously, the shim 43 and the tab 42 allow for positioning the support 40 to limit the constraints exerted by the support 40 on the mechanical damper 74.

The operation of the device is now explained.

When the circuit breaker 12 switches to the tripped configuration due to a fault such as an overload or short circuit, or following a user command, the circuit breaker 12 generates noise, representative of the trip intensity Id, as well as mechanical vibrations in the solid parts forming the circuit breaker 12. In particular, the generated noise is caused by detonations and by so-called acoustic pressure variations, which are representative of the trip intensity. The detonations can cause pressure variations up to several hundred thousand pascals, which can damage the microphone 70. The acoustic pressure variations are, for example, on the order of a thousand pascals, and the maximum acoustic pressure variations are, for example, on the order of 6000 Pa, i.e., about 169.5 dB.

The attenuator 44, particularly due to the attenuating membrane 50, attenuates the noise generated by the circuit breaker 12 when same switches to the tripped configuration. More precisely, the attenuator 44 attenuates both the detonations, thus protecting the microphone 70, and the acoustic pressure variations. Advantageously, the attenuator 44 attenuates the acoustic pressure variations to obtain at input of the microphone 70 an attenuated noise generated by maximum pressure variation values of about 135 dB, which limits the risk of saturation of the microphone 70. Thus, when the microphone 70 receives the noise attenuated by the attenuator 44, same is capable of measuring it.

Moreover, the attenuator 44 attenuates the acoustic pressure variations constantly, regardless of the frequency thereof. In practice, the attenuator 44 attenuates the pressure variations constantly for a predefined frequency spectrum. For example, the frequency spectrum is between 20 Hz and 15 kHz, preferably between 30 Hz and 10 kHz. In other words, the attenuated noise is not distorted over the frequency spectrum between 30 Hz and 10 kHz. Thus, the attenuated noise is representative of the noise generated by the circuit breaker 12, and therefore, of the trip intensity Id.

The microphone 70 measures the ambient noise, which is, in the case of the device 20, the noise attenuated by the attenuator 44, and generates an output signal, representative of the attenuated noise. The electronic control unit 38 receives the output signal emitted by the microphone 70 and estimates the trip intensity Id of the circuit breaker's trip current from the output signal. Advantageously, the output signal is considered by the electronic control unit 38 only when the electronic control unit 38 receives an acquisition command, emitted, for example, by a micro-contact. The micro-contact is configured to detect the circuit breaker 12 tripping and then emits the acquisition command.

The mechanical vibrations generated by the circuit breaker 12 are transmitted to the device 20, notably through the casing 22, which then transmits said mechanical vibrations to the plate 32. To prevent the transmission thereof to the microphone 70, the mechanical vibrations are attenuated by the assembly formed by the support 40 and the tab 42 and advantageously, by the mechanical damper 74. The assembly formed by the support 40 and the tab 42 allows the support 40 to be decoupled from the plate 32 and thus limiting the transmission of mechanical vibrations from the circuit breaker 12 to the support 40, and therefore to the microphone 70 fixed on the support 40. The mechanical damper 74 reduces the mechanical vibrations still transmitted to the tab 42 and the support 40. Thus, the mechanical vibrations transmitted to the microphone 70 from the support 40 are limited, preventing said mechanical vibrations from masking the attenuated noise obtained from the noise produced by the circuit breaker 12.

The noise and mechanical vibrations generated by the circuit breaker 12 cause resonance phenomena, generating additional noise, the frequency thereof being, for example, between 20 kHz and 35 kHz. Advantageously, the membranes 64 attenuate noise with a frequency higher than 20 kHz, without attenuating other noises, thus limiting the risk of saturation of the microphone 70 caused by resonance phenomena. The membranes 64 thus function as acoustic impedances.

The attenuator 44, the assembly formed by the support 40 and the tab 42, and advantageously, the mechanical damper 74 and the membranes 64 limit the presence of interference in the output signal and thus provide the most accurate possible estimation of the trip intensity Id by the electronic control unit 38.

1. An acoustic device for estimating a trigger intensity of a trip current flowing in a circuit breaker, the device comprising:
a casing configured to be attached to the circuit breaker;
a plate, integrated inside the casing, the plate extending along a main plane;
a support, integrated inside the casing, the support extending parallel to the main plane, a tab connecting the support and the plate, the support being connected to the plate only via the tab;
a microphone, fixed to the support;
an attenuator, fixed to the support, the support extending between the microphone and the attenuator, the attenuator comprising:
a housing with a housing orifice, passing through and extending along a housing axis, and
an attenuating membrane, received in the housing and covering the housing orifice; and
an electronic control unit, connected to the microphone,
the attenuator being configured to attenuate noise generated by the circuit breaker, the noise being representative of the trigger intensity, the microphone being configured to measure the noise attenuated by the attenuator, and emit an output signal representative of the attenuated noise, and the electronic control unit being configured to receive the output signal emitted by the microphone and estimate the trigger intensity of the circuit breaker's trip current from the output signal.

2. The device according to claim 1, wherein the attenuator further comprises a washer, with a washer orifice, the washer orifice passing through and extending along a washer axis, the washer being received in the housing so that the housing and washer axes and coincide, the washer being in contact with the attenuating membrane, and the attenuating membrane covering the washer orifice.

3. The device according to claim 1, further comprising a mechanical damper, fixed to the casing, surrounding the support and the attenuator, and leaving the microphone and the housing orifice free, the mechanical damper being configured to damp mechanical vibrations of the device.

4. The device according to claim 1, wherein the casing comprises a shim, the tab being supported against the shim to position the support at a distance from the plate along an axis perpendicular to the main plane.

5. The device according to claim 1, wherein:
the support comprises a support orifice, the support orifice passing through along a support axis;
the microphone is fixed on the support to cover the support orifice; and
the attenuator is fixed to the support so that the housing, washer, and support axes, and coincide.

6. The device according to claim 1, wherein the casing comprises an acoustic port, with at least one opening, the support facing the acoustic port and the attenuator is positioned between the support and the acoustic port.

7. The device according to claim 1, wherein the attenuator is fixed to the support by an adhesive film, the adhesive film comprising at least two adhesive layers and at least one membrane, interposed between two of the at least two adhesive layers, one of the at least two adhesive layers being glued to the attenuator and another of the at least two adhesive layers being glued to the support.

8. The device according to claim 7, wherein the or each membrane comprises woven fibers.

9. The device according to claim 7, wherein the or each membrane comprises non-woven fibers.

10. An electrical protection assembly comprising a circuit breaker, the circuit breaker being configured to be connected between a source and a load, and being configured to switch from an armed configuration, wherein the circuit breaker conducts a current flowing between the source and the load, to a tripped configuration, wherein the circuit breaker electrically isolates the load from the source, when a trip current of trip intensity flows in the circuit breaker, the switch from the armed configuration to the tripped configuration generating noise representative of the trip intensity, the circuit breaker comprising a housing, the electrical protection assembly further comprising a device according claim 1, the device's casing being fixed to the housing.

11. An electrical installation comprising a source, a load connected to the source, and an electrical protection assembly according to claim 10, connected between the source and the load.
